(19) United States
(12) Patent Application Publication
(10) Pub. No.: US 2015/0359143 A1
(43) Pub. Date: Dec. 10, 2015

(54) METHOD OF HEAT TRANSFER IN POWER ELECTRONICS APPLICATIONS

(71) Applicant: ABB Technology Oy, Helsinki (FI)

(72) Inventors: Mika SILVENNOINEN, Espoo (FI); Juha MARTINMAA, Vantaa (FI); Heikki MÖRSKY, Espoo (FI)

(73) Assignee: ABB Technology Oy, Helsinki (FI)

(21) Appl. No.: 14/734,437

(22) Filed: Jun. 9, 2015

(30) Foreign Application Priority Data
Jun. 10, 2014 (EP) 14171778.5

(51) Int. Cl. H05K 7/20; B23P 15/26

(52) U.S. Cl. CPC H05K 7/20509; B23P 15/26

(57) ABSTRACT

An exemplary method of heat transfer in power electronics applications is disclosed, wherein a metal foil including at least about 50% of tin, based on a total amount of metals contained in the metal foil, is used as a thermal interface material between a base plate of a heat-generating component and a heat sink. The metal foil is disposed on a heat sink. A base plate of a heat generating component or module is disposed on the heat sink covered by the metal foil to provide a power electronics device. A clamping force is applied to the power electronics assembly to provide a cooled power electronics assembly.

### RELATED APPLICATION(S)

This application claims priority under 35 USC §119 to European application No. 14171778.5 filed in Europe on Jun. 10, 2014. The entire content of which is hereby incorporated by reference in its entirety.

### FIELD

The present disclosure relates to a method of heat transfer in power electronics applications. More particularly, the invention relates to a use of a metal foil as a thermal interface material in power electronics applications.

### BACKGROUND INFORMATION

Power electronic components and modules that are used in power electronic devices for switching high currents need to be kept below a certain temperature. A power electronic module contains multiple of switch components, such as power diodes or insulated gate bipolar transistors (IGBT). An example of a device containing power electronic components can be an inverter. Inverters produce alternating voltage by switching DC voltage pulses in a high frequency to a load. Each time the switches of an inverter are operated, a relatively large power can be dissipated in the switches.

The base plate of the component or the module can be thermally connected to a heat sink such that the heat generated in the module or component can be lead through the baseplate to the heat sink. Thermal interface materials (TIMs) are often provided to establish heat transfer from the baseplate of the heat-generating component or module to a heat sink. There are a large variety of TIMs often used in these applications, including thermal greases, phase change materials, thermal tapes and metal foils.

WO 2007/050712 A2 discloses a thermally conductive patterned metal foil for facilitating heat dissipation from an integrated circuit device to a heat sink. The metal foil can be formed of an alloy of lead, indium, tin and other malleable metals.

Also, metallic TIMs based on an indium metal are known in IGBT applications. An example of such TIMs can be commercially available Heat-Spring® products in a form of metal foil from Indium Corporation. A drawback of the Heat-Spring products can be that they are expensive due to the large amount of indium included in the foil. Further, the large amount of indium in the foil makes the foil brittle, and therefore the mounting of the foil between the heat sink and the base plate of the module has to be carried out with care as the brittle foil brakes easily during the mounting.

There can be a need for an inexpensive, efficient, reliable, stable, easy-to-handle thermal interface material suitable for use in power electronics applications.

### SUMMARY

An exemplary method of heat transfer in power electronics applications is disclosed, comprising: a metal foil including at least about 50% of tin that is based on a total amount of metals contained in the metal foil, the metal foil is used as a thermal interface material between a base plate of a heat-generating component and a heat sink.

### BRIEF DESCRIPTION OF THE DRAWINGS

FIG. 1 illustrates a simplified example of an assembly including an IGBT module, a heat transfer metal foil, and a heat sink according to an exemplary embodiment of the present disclosure.

### DETAILED DESCRIPTION

Exemplary embodiments of the present disclosure provide a method of heat transfer in power electronics applications, wherein a separate metal foil including at least about 50% of tin, based on a total amount of metals contained in the metal foil, can be used as a thermal interface material between a base plate of a heat-generating component and a heat sink.

According to an exemplary embodiment of the present disclosure, a method for producing a power electronics assembly, includes the steps of disposing a separate metal foil including at least about 50% of tin, based on a total amount of metals contained in the metal foil, disposing a base plate of a heat generating component or module on the heat sink covered by the metal foil to provide a power electronics device, applying a clamping force to the power electronics assembly to provide a cooled power electronics assembly.

According to another exemplary embodiment of the present disclosure, metal foil can be used including at least about 50% of tin, specifically at least about 90% of tin, more specifically at least about 99.9% of tin, based on a total amount of metals contained in the metal foil, for heat transfer in power electronics applications.

It should be understood that the same effect of a prior art indium-based metal foil in power electronics applications can be achieved with a metal foil containing a large amount of more inexpensive tin. Indium has a better thermal conductivity than tin and needs no high clamping force applied in the power electronics application. Good heat transfer characteristics of a tin-based metal foil are achieved as long as the clamping force applied can be sufficient.

Exemplary embodiments of the present disclosure provides an improved means for heat transfer in power electronic application of a metal foil. The exemplary metal foil described herein can be inexpensive, efficient, reliable, stable, easy-to-handle thermal interface material which can be easily mounted between the base plate of the cooled component or module and a heat sink. The metal foil does not exhibit a pump-out phenomenon that often occurs with viscous TIMs.

Exemplary embodiments of the present disclosure a method of heat transfer in power electronics applications, wherein a separate metal foil including at least about 50% of tin, based on a total amount of metals contained in the metal foil, can be used as a thermal interface material between a base plate of a heat-generating component and a heat sink.

According to an exemplary embodiment disclosed herein, the metal foil includes at least about 90% of tin, based on a total amount of metals contained in the metal foil. In another embodiment, the metal foil includes at least about 99.9% of tin, based on a total amount of metals contained in the metal foil.

In addition to tin (Sn), the metal foil includes one or more other malleable metals. In an embodiment, an amount of the other malleable metals can be at most of about 50%. In another embodiment, the amount can be at most of about 10%. In a further embodiment, the amount can be at most of about 0.1%. In an embodiment, the other malleable metals are selected from a group consisting of silver (Ag), aluminium (Al), arsenic (As), gold (Au), bismuth (Bi), cadmium (Cd), chromium (Cr), copper (Cu), iron (Fe), mercury (Hg), indium (In), nickel (Ni), lead (Pb) and a mixture thereof.

The metal foil has a characteristic softness and formability which allows the metal foil to be well conformed to the surface irregularities.

The metal foil used in the exemplary embodiment can be free of fat and oil.

The metal foil does not melt or change its state of matter.

The metal foil can be provided as a monolayer or a multilayer foil. When the metal foil includes more than one layer, the composition of the layers can be similar to or different from each other. In an embodiment, the metal foil can be a monolayer foil.

In an exemplary embodiment for the present disclosure, at least one outer surface of the metal foil can be patterned. The metal foil can have various types of patterned surfaces. Suitable patterned surfaces are described for example in WO 2007/050712 A2. The patterned surface can be uniform or non-uniform. The one-sided or double-sided patterned surfaces facilitate the metal foil to better adapt to the irregularities of the surfaces with which the metal foil can be attached. The patterned surface(s) thus provide(s) enhanced heat dissipation from a heat-generating component to a heat sink.

The metal foil can have a thickness in the range of about 50 μm to about 200 μm. According to an exemplary embodiment described herein, the thickness can be in the range of about 100 μm to about 150 μm. In another embodiment, the thickness can be about 150 μm.

According to yet another exemplary embodiment, the metal foil can be provided in a form of a roll. In another embodiment, the metal foil can be provided in sheets.

The metal foil can be used in any power electronics application where a thermal interface material for heat transfer from a heat-generating component or module to a heat sink can be needed. According to an exemplary embodiment, the heat-generating component can be an insulated gate bipolar transistor (IGBT). According to another exemplary embodiment, the heat generating module can be a power electronics module containing one or multiple of electronic switch components, such as diodes or IGBTs.

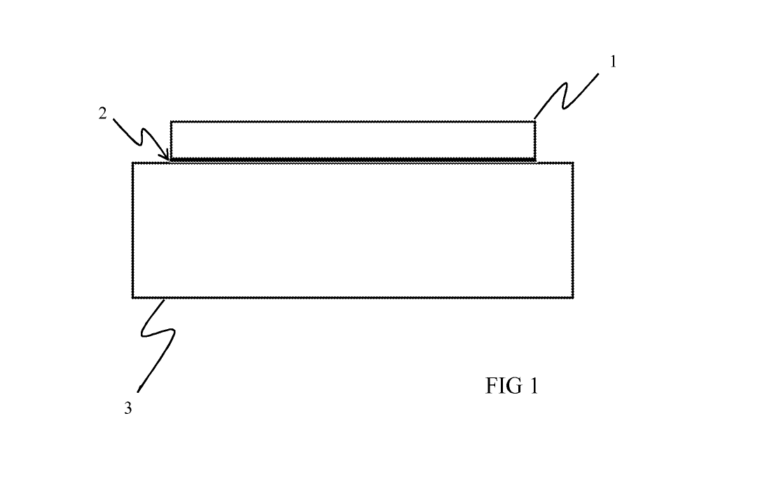

FIG. 1 illustrates a simplified example of an assembly including an IGBT module, a heat transfer metal foil, and a heat sink according to an exemplary embodiment of the present disclosure. As shown in FIG. 1 an assembly includes an IGBT module 1, a heat sink 3 and an exemplary heat transfer metal foil 2 disposed between the module 1 and the heat sink 3. The module and the heat sink are attached to each other through mechanical fastening. Heat sinks are often provided with threaded holes to match through holes made in the base plate of the module. The heat transferring metal foil includes also holes for attachment such that when the metal foil can be placed on top of the base plate, the threaded holes of the heat sink, the holes of the metal foil and the holes of the base plate are at the same position allowing a screw to penetrate through the holes. Instead of providing threaded holes to the heat sink, through holes can be made, whereby the attachment can be carried out by a bolt and a nut attachment.

For the heat transfer to be effective, the tightening torque of the screws or bolts should be high enough so that a desired pressure or clamping force can be obtained between the heat sink and the base plate. The thermal resistance of the metal foil drops in proportion to the applied pressure. For the known indium-based metal foil a pressure of approximately 50 psi can be called for whereas for a tin-based metal foil the needed pressure can be approximately in the range of about 100 psi to about 150 psi. Tightening torque of the screws or bolts can be in the range of 1 to 6 Nm for obtaining desired pressure.

Holes for attachment of the base plate and the heat sink are provided to the corners of the module. In larger modules screw holes can also be situated on the sides of the module such that the longer dimension of the module may have four holes evenly distributed making together eight attachment points, for example.

For providing evenly distributed pressure between the base plate and the heat sink, the metal foil can be thicker in the areas between the attachment points. Although the base plate and the heat sink are rigid component, the base plate may bend during the use due to temperature changes, for example. The bending of the base plate affects the heat transfer as the pressure between the base plate and the heat sink may change. When the metal foil can be made thicker in the areas between the attachment points, the heat transfer is not hindered as much as with a foil with a uniform thickness. The thickness of the metal foil can vary at most of about 100% in the range of about 50 μm to about 200 μm.

Another exemplary embodiment of the present disclosure can be to provide a method for producing a power electronics assembly, including the steps of disposing a separate metal foil including at least about 50% of tin, based on a total amount of metals contained in the metal foil on a heat sink, disposing a base plate of a heat generating component or module on the heat sink covered by the metal foil, applying a clamping force to the power electronics assembly.

The metal foil can be disposed on the heat sink at a room temperature. The heat generating component is not subjected to thermal treatment, such as reflow operation, during installation of the metal foil.

The metal foil forms a separate thermal interface material which is not adhered to the heat sink. The foil can thus be easily detached from the heat sink by opening fastening screws or bolts of the power electronics assembly.

Exemplary embodiments of the present disclosure provide a use of metal foil, including at least about 50% of tin, based on a total amount of metals contained in the metal foil, for heat transfer in power electronics applications. According to an exemplary embodiment disclosed herein, the metal foil includes at least about 90% of tin. In another embodiment, the metal foil includes about 99.9% of tin.

Temperature of a baseplate of an IGBT module was measured below an IGBT component and below its parallel diode. Table 1 shows that the temperatures of the two components achieved with the exemplary metal foil of the present disclosure are essentially similar to those achieved with prior art metal foils, indicating an excellent performance of the exemplary metal foil described herein as a thermal interface material in a power electronics application.

TABLE 1

| | In52%/Sn48% | In 99.9% | Sn 99.9% |
|---|---|---|---|
| Air In (Temp. ° C.) | 40.0 | 40.0 | 40.0 |
| IGBT (Temp. ° C.) | 117.0 | 117.1 | 118.9 |
| DIODE (Temp. ° C.) | 120.3 | 119.9 | 121.8 |

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A method of heat transfer in power electronics applications, comprising:
a metal foil including at least about 50% of tin that is based on a total amount of metals contained in the metal foil, the metal foil is used as a thermal interface material between a base plate of a heat-generating component and a heat sink.

2. The method of claim 1, wherein the metal foil comprises at least about 90% of tin,

3. The method of claim 2, wherein the metal foil comprises at least about 99.9% of tin.

4. The method of claim 1, wherein the metal foil further comprises one or more metals selected from a group consisting of: silver, aluminium, arsenic, gold, bismuth, cadmium, chromium, copper, iron, mercury, indium, nickel, lead and a mixture thereof.

5. The method of claim 1, wherein the metal foil is fat-free and oil-free.

6. The method of claim 1, wherein the metal foil comprises one or more layers, the composition of which can be similar to or different from each other.

7. The method of claim 1, wherein at least one outer surface of the metal foil is patterned.

8. The method of claim 1, wherein the metal foil has a thickness in the range of about 50 μm to about 200 μm.

9. The method of claim 8, wherein the thickness of the metal foil varies at up to about 100%.

10. The method of claim 8, wherein the metal foil has a thickness in a range of about 100 μm to about 150 μm.

11. The method of claim 10, wherein the metal foil has a thickness in a range of about 150 μm.

12. The method of claim 1, wherein the metal foil is a roll or sheets.

13. The method of claim 1, wherein the heat generating component is an insulated gate bipolar transistor (IGBT).

14. A method for producing a power electronics assembly, comprising:
disposing a separate metal foil having at least about 50% of tin, based on a total amount of metals contained in the metal foil defined in claim 1, on a heat sink;
disposing a base plate of a heat generating component or module on the heat sink covered by the metal foil to provide a power electronics device; and
applying a clamping force to the power electronics assembly to provide a cooled power electronics assembly.
